(19) United States
(12) Patent Application Publication
(10) Pub. No.: US 2008/0081483 A1
(43) Pub. Date: Apr. 3, 2008

(54) PULSED PLASMA ETCHING METHOD AND APPARATUS

(75) Inventor: Hanming Wu, Shanghai (CN)

Correspondence Address: SQUIRE, SANDERS & DEMPSEY L.L.P., 1 MARITIME PLAZA, SUITE 300, SAN FRANCISCO, CA, 94111, US

(73) Assignee: SEMICONDUCTOR MANUFACTURING INTERNATIONAL (Shanghai) CORPORATION, Shanghai (CN)

(21) Appl. No.: 11/618,504

(22) Filed: Dec. 29, 2006

(30) Foreign Application Priority Data
Sep. 30, 2006 (CN) 200610116855.6

(51) Int. Cl. H01L 21/306

(52) U.S. Cl. 438/714; 156/345.35; 257/E21.218

(57) ABSTRACT

A plasma etching method includes preparing in a reaction chamber a semiconductor substrate on which a material layer to be etched is provided; and injecting an etching gas into the reaction chamber, the etching gas being ionized through an RF (Radio Frequency) power source to generate a plasma, wherein the RF power source outputs RF power in a pulse output mode. The plasma etching apparatus includes a reaction chamber adapted to contain an etching gas; and an RF power source adapted to output RF power for excitation of the etching gas to generate plasma, wherein the apparatus further include a pulse control circuit adapted to control the RF power source to output RF power in a pulse output mode. With the invention, the plasma for etching can be generated in a pulse output mode, thus improving a precision of an endpoint where the etching can be disabled.

This application claims the priority of Chinese Patent Application No. 200610116855.6, filed Sep. 30, 2006, the entire disclosure of which is incorporated herein by reference.

### FIELD OF THE INVENTION

The present invention relates to the field of semiconductor integrated circuit manufacturing technologies, and in particular to a plasma etching method and apparatus.

### BACKGROUND OF THE INVENTION

As semiconductor manufacturing technologies advance rapidly, integrated circuits tend to have a more rapid operational rate, a larger data storage capacity and more functions. Semiconductor wafers are striding forward to a higher component density and a high integration level. A characteristic dimension of a gate line width of a semiconductor device, such as a MOS (Metal Oxide Semiconductor) device, becomes thinner, and a length thereof becomes shorter.

In a process of manufacturing a metal oxide semiconductor device, an insulation layer such as a silicon oxide film or a silicon nitride film is first formed on a silicon substrate. The insulation layer is patterned, and an opening is formed on the insulation layer through photolithography and etching processes. The opening has a shape corresponding to a shape of an isolation area which defines an active area. With the use of a silicon nitride film as a mask, the silicon substrate is etched to form an isolation trench. Then an insulation layer such as a silicon oxide film is deposited through a Chemical Vapor Deposition (CVD) method, etc., so as to bury or embed the insulation layer into the isolation trench, which is in turn planarized through a Chemical Mechanical Polishing (CMP) method.

In a subsequent process, a gate oxide layer and a polysilicon layer are formed on a surface of the active area (Active Area, AA) on both sides of the trench. In order to avoid a short channel effect and to obtain a maximum drain current, a thickness of a gate oxide layer becomes thinner. The use of a thin gate oxide layer can enhance a coupling of a gate electrode and a channel carrier, and thus the property of a transistor can be more approximate to that of a long channel apparatus. Because the drain current is approximately in proportion to a gate capacitance, a reduced thickness of the gate oxide layer can be advantageous to a deep submicron process. For example, for a 65 nm or below process technology, the physical thickness of the gate oxide layer can be approximately 10 to 12 Å.

Thereafter, a photoresist layer is formed on a surface of the polysilicon layer, and is patterned to define a location of a grid. With the use of the mask-defined photoresist pattern, the polysilicon layer is etched through an anisotropic etching method to form a gate electrode. A gate electrode with an extremely fine characteristic dimension of a line width can be formed through a high-precision patterning process. Then, a lightly doped ion implantation is performed to form an extension region of a source/drain region and an LDD (Lightly Doped Drain) region to prevent a short channel effect. An insulation film such as a silicon oxide film is deposited, and is etched anisotropically to form a sidewall spacer layer. The source/drain region is doped heavily with a high concentration using the photoresist pattern and the sidewall spacer layer as a mask, and then is annealed to activate implanted impurity ions to form a source and a drain.

During the above manufacturing processes of a metal oxide semiconductor device in the prior art, the residual photoresist mask on top of the gate electrode has to be completely stripped after the lightly or heavily doping process. A plasma etching process is usually used for the stripping, where an etching gas, such as a mixture of oxygen and argon, is injected into a reaction chamber. Under a given temperature and pressure, an RF (Radio Frequency) voltage is supplied with a given power through an RF power source, and the oxygen is ionized in a plasma generation space to generate high-energy oxygen plasma group (ion bombardment energy can be higher than 10 eV). The photoresist on the top of the gate electrode is bombarded by the high-energy ions in the oxygen plasma group so as to be oxidized for the purpose of stripping the residual photoresist. FIG. 1 shows a sectional view of stripping the photoresist through the plasma, and as shown, a source 130 and a drain 140 are formed in a substrate 100, and a photoresist 110 on a surface of a gate 150 is stripped using oxygen plasma 160.

Due to a previous process, such as an acid washing or a baking process, a layer of carbon crust 120 tends to occur on the surface of the residual photoresist 110. This layer of carbon crust 120 increases the difficulty in stripping the photoresist 10, and the plasma bombardment energy has to be increased for the stripping. In an existing etching process, the energy is output continuously through an RF power source. For example, as described in Chinese Patent Application No. 200410058187.7, a layer to be etched is bombarded through the continue plasma. Such a continuous energy output has a serious potential risk in a control of etch termination. For example, during the stripping of the photoresist, the bombardment energy of oxygen plasma has to be enhanced due to the presence of the crust. Moreover, during the stripping of the photoresist layer through the oxygen plasma that is output continuously, the oxygen plasma tends to penetrate the gate oxide layer, and further enters the active area and reacts with the silicon under the gate oxide layer to generate silicon oxide, which can be stripped in a subsequent wet-cleaning process, resulting in a serious loss of silicon (Si loss or Si recess) in the AA region. Thus, a recess may be generated inevitably in the source region and the drain region. FIG. 2 shows a schematic diagram of a device after the stripping of the photoresist through the existing etching process, and as shown, a recess 170 is generated at source region 130 and a drain region 140 on the substrate 100, and such a recess typically has a height of approximately 40 Å. For a device with a 0.13 um node, a thickness of the gate oxide layer is approximately 70 to 200 Å, and an LDD depth is approximately 400 Å. A recess of 40 Å generally has no substantial influence on a CMOS device of 0.13 um and above. However, for a device of 65 nm and below, the thickness of the gate oxide layer is only approximately 10 Å, and an LDD depth is below approximately 250 Å. In this case, the recess resulted from the Si loss can destroy the LDD region and may seriously impair the performance of the device.

### SUMMARY OF THE INVENTION

In view of the above, an object of the invention is to provide a plasma etching method and apparatus which can improve the precision of an endpoint where the etching can be disabled.

To this end, an embodiment of the invention provides a method for plasma etching comprising:

preparing in a reaction chamber a semiconductor substrate on which a material layer to be etched is provided; and

injecting an etching gas into the reaction chamber, the etching being ionized through an RF power source to generate plasma, wherein:

the RF power source outputs RF power in a pulse output mode.

In a preferable embodiment, the RF power source outputs RF power ranging from 100 to 2200 W; a time range for the RF power source to output RF power is 5% to 90% relative to a whole etching time range; a pressure in the reaction chamber ranges from 3 to 500 mTorr; a temperature of the semiconductor substrate ranges from 20 to 180° C.; the material layer is a photoresist layer, a metal layer or a medium layer, the metal layer is one of copper, titanium, tungsten, tantalum, nickel and cobalt, and the medium layer is one of silicon oxide, silicon nitride, silicon oxynitride, polysilicon, hafnium oxide, hafnium silicon oxide and hafnium silicon oxynitride; and the etching gas is one of O₂, N₂, Ar, He, Ne, Cl₂, O₂—He, HBr and a fluorine-containing gas, and the fluorine-containing gas is one of CF₄, CH₂F₂, CHF₃ and SF₆.

Another embodiment of the invention provides a plasma etching apparatus comprising:

a reaction chamber adapted to contain an etching gas; and

an RF power source adapted to output RF power for excitation of the etching gas to generate plasma, wherein:

the apparatus further comprises a pulse control circuit adapted to control the RF power source to output RF power in a pulse output mode.

In a preferable embodiment, the RF power source outputs RF power ranging from 100 to 2200 W; a time range for the RF power source to output RF power is 5% to 90% relative to a whole etching time range; a pressure in the reaction chamber ranges from 3 to 500 mTorr; and a wafer temperature ranges from 20 to 180° C.

A further embodiment of the invention provides a plasma etching apparatus comprising:

an RF power source adapted to output RF power;

a pulse control circuit adapted to control the RF power source to output RF power; and

a first reaction chamber and a second reaction chamber, wherein:

the first reaction chamber contains an etching gas, the RF power source outputs RF power in a pulse output mode through the pulse control circuit, and an etching gas is ionized in the first reaction chamber to generate plasma entering the second reaction chamber to etch a material layer on a wafer surface.

In a preferable embodiment, the RF power source outputs RF power ranging from 100 to 2200 W; a time range for the RF power source to output RF power is 5% to 90% relative to a whole etching time range; a pressure in the first reaction chamber ranges from 3 to 500 mTorr; a temperature of the wafer ranges from 20 to 180° C.; and the etching gas includes oxygen and water vapor.

The embodiments of the invention can be advantageous over the prior art for at least the following reason.

The plasma etching method and apparatus can output power in a pulse mode, that is, the RF power source for generating plasma outputs RF power in a pulse mode, and the etching gas is ionized in a pulse mode to generate the plasma. Further, a film layer to be etched can be etched by the plasma in an intermittent not continuous mode, and thus the etching effect of the plasma can be controlled and buffered. With such a pulse plasma etching mode, a proportion of the time width in which the plasma source outputs power relative to the whole pulse period can be adjusted as needed. That is, during the whole etching phase, an etching interval of time for the plasma can be set as needed, and the electron temperature and the sheath voltage of the plasma can be adjusted to be within an appropriate range. During an etching process for a semiconductor device of 65 nm and below, the inventive plasma etching method and apparatus can precisely control an etching depth and improve the precision of a point where the etching can be disabled. The etching depth can be controlled precisely during a process such as the stripping of the photoresist, the etching of the gate oxide layer, etc., thus resulting in elimination of any recess occurring in the active area and the LDD region.

### BRIEF DESCRIPTION OF THE DRAWINGS

The above and other objects, characteristics and advantages of the invention will be more apparent from the following descriptions of preferred embodiments of the invention as shown in the drawings unnecessarily drawn to scale, where identical reference numbers indicate alike or identical parts, and thicknesses of a layer and a region are enlarged for clarity:

FIG. 1 shows a sectional view of the stripping of a photoresist with plasma;

FIG. 2 shows a schematic diagram of a device after the stripping of the photoresist through an existing etching process;

FIG. 3 shows a schematic diagram of a plasma pulse output mode according to an embodiment of the invention;

FIG. 4 shows a schematic curve of a relationship between a pulse width and a sheath voltage;

FIG. 5 shows a schematic diagram of a plasma etching apparatus according to a first embodiment of the invention;

FIG. 6 shows a schematic diagram of a device for which the photoresist has been stripped through the etching apparatus shown in FIG. 5; and

FIG. 7 shows a schematic diagram of a plasma etching apparatus according to a second embodiment of the invention.

### DETAILED DESCRIPTION OF THE EMBODIMENTS

In order to make the above objects, characteristics and advantages of the invention more apparent, preferred embodiments of the invention will be described in detail with reference to the drawings.

Details will be presented in the following for a full understanding of the invention. However, the invention can be implemented in any way different from those disclosed here, and variations and modifications thereto can be obvious to those skilled in the art without departing from the scope of the invention. Note that the invention shall not be limited to the disclosed embodiments in the following.

A plasma etching process is important for semiconductor manufacturing technologies, and can be used for etching a medium layer including a silicon oxide layer, a silicon nitride layer, a polysilicon layer, etc., and a material with a high dielectric constant such as hafnium oxide, hafnium silicon oxide, hafnium silicon oxynitride, etc., for etching a metal layer such as copper, titanium, tungsten, tantalum, nickel, cobalt, etc., and for stripping the plasma ashing of an organic material of a photoresist, an anti-reflection layer, etc. An etching agent is typically in the form of gas including O₂, N₂, Ar, He, Ne, Cl₂, O₂—He, HBr, a fluorine-containing gas and a mixture thereof. Particularly, the etching of a dielectric layer primarily uses a fluorine-containing gas such as CF₄, CH₂F₂, CHF₃, SF₆, etc.; the etching of a metal primarily uses a gas such as Cl₂, Br₂, HBr, etc.; and the plasma ashing primarily uses O₂ for an organic material of a photoresist, an anti-reflecting layer, etc.

An etching gas is injected and an electron stream is introduced into a reaction chamber under a low-pressure environment. Electrons are accelerated through an RF electric field generated using an RF power source. Respective electrons collide with gas molecules for a transfer of kinetic energy, and the gas molecules are ionized to generate plasma. In addition to the use for etching, the generated plasma can also be used for such a process as deposition, ion implantation, etc.

Plasma etching is a type of dry etching, where a gaseous chemical etching agent is used to react with a material so as to form a volatile byproduct removable from a wafer. The plasma can generate free radicals liable to a chemical reaction (a radical refers to an ionized atom or molecule), and these free radicals may lead to a significant increase of an etching rate. The plasma also can cause an ion bombardment on a surface of the wafer. The bombardment can not only physically remove a material from the surface, but also destroy a chemical bond between atoms on the surface, thus resulting in a considerable increase of an etching reaction rate.

As an ionized gas with positive and negative charges of equal quantities, the plasma is comprised of ions, electrons and neutral atoms or molecules. Three important collisions for the plasma are Ionization, Excitation-Relaxation Impact and Dissociation collisions. These collisions can generate and maintain the plasma respectively, cause a gas glow discharge, and generate free radicals liable to a chemical reaction for enhancement of the chemical reaction. A Mean Free Path (MFP) is a mean distance that one particle can move prior to collision with another particle. A lowered pressure may result in an increased MFP and collision energy of ions, and also in reduced ion dispersion, which can be advantageous in obtaining a vertically etched profile.

During processes of plasma film-synthesizing and plasma etching, a bias voltage (a DC, RF or pulse bias voltage) is typically applied on a wafer, and thus a non-electro neutral region, i.e. a plasma sheath, can be formed in the vicinity of the wafer. A sheath electric field has a direct control over an energy distribution and an angle distribution of ions incident upon the wafer, and hence an influence on a process of the plasma. An electric field formed in the vicinity of an electrode due to a difference between positive and negative charges is also referred to as a Sheath voltage. A potential of the plasma is typically higher than that of the electrode. Upon generation of the plasma, electrons with a small mass and a rapid motion can lead to the electrode with negative charges. Since ions with positive charges are accelerated through the sheath voltage to reach the electrode at a lower potential, a higher plasma potential can induce an ion bombardment. In this regard, an ion group can be accelerated through the sheath voltage to move toward the electrode, but a too high sheath voltage may cause an excessive ion bombardment upon the wafer.

For a node of 65 nm and below, a characteristic dimension of a device is very tiny. During an etching process of a semiconductor device, a region such as an ultra shallow junction composed of an extremely thin gate oxide layer and an extremely shallow extension doped region is liable to being damaged to different extents due to plasma etching. For example, during the stripping of the photoresist with plasma, a gate oxide layer is being etched simultaneously, and a recess may occur in the active area and the LDD region. For this reason, the plasma is required to be provided with a sufficient base flow for a full reaction with a material to be etched, and also an ion flow shall be reduced as much as possible for a reduced etching strength per unit time. Thus during the etching process, the material to be etched can react fully with the radicals, and a damage due to etching of another material layer for which no etching is required can be minimized.

In a plasma etching method and apparatus according to an embodiment of the invention, pulse output power is used to ionize in a pulse mode an etching gas to generate plasma that etches a film layer to be etched in an intermittent not continuous mode. Thus the etching effect of the plasma can be controlled and buffered. In such a pulse plasma etching mode, a ratio between a time width of power output from a plasma source and a whole pulse period can be adjusted as needed. That is, during the whole etching phase, a plasma etching interval of time can be set as needed, and an electron temperature and a sheath voltage of the plasma can be adjusted to be within an appropriate range, thus resulting in a required base flow and ion flow and a good etching effect.

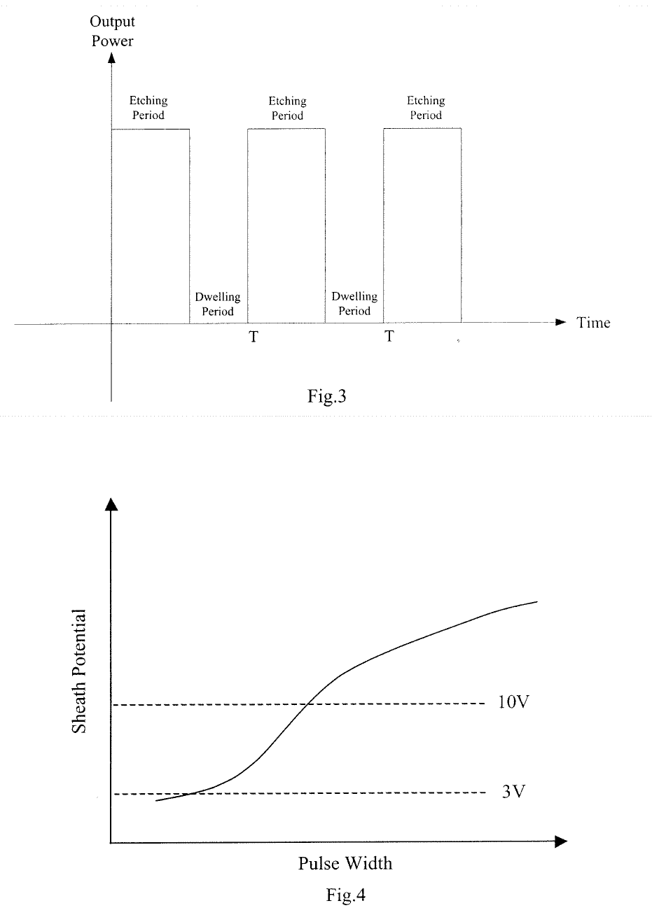

FIG. 3 shows a schematic diagram of a plasma pulse output mode according to the inventive method. This diagram is merely illustrative of an example without limitation of the scope of the invention. As shown, an X-axis represents a period of time required from a start to an end of an etching process, and a Y-axis represents an output power of an RF power source. The RF power source outputs RF power in a pulse mode, that is, during an etching process, the RF power source outputs RF power in an intermittent not continuous mode for excitation of an etching gas. A period T of an etching phase includes an output period and a dwelling period, and thus the generation of plasma is periodic. In the output period, the plasma etches a material layer on a substrate surface. In the dwelling period, the RF power source disables excitation and plasma output. Moreover, a percentage of the output period relative to the whole etching period can be controlled in a range from 5% to 90%. Thus, a width of the pulse output period can be adjusted according to the material and thickness of the material layer.

FIG. 4 shows a schematic curve of a relationship between a pulse width and a sheath voltage, which is merely illustrative of an example without limitation of the scope of the invention. As described above, the sheath voltage has a direct influence on the energy distribution and the angle distribution of ions incident upon a wafer, and hence an influence on a process of the plasma. Generally, the higher the sheath voltage is, the higher the ion bombardment energy from ions with positive charges accelerated by the sheath voltage can be. The sheath voltage is associated with the output power of the RF power source and the bias voltage, and when the bias voltage is unchanged, the sheath voltage can increase as the output power of the RF power source increases. With the inventive method, the output power of the RF power source can be adjusted conveniently through adjustment of the width of the pulse output period, and thus the sheath voltage can be adjusted. As shown in FIG. 4, the output power of the RF power source is adjusted through adjustment of the pulse width, and thus the sheath voltage can be changed. In the inventive plasma etching method, the sheath voltage can be adjusted to be within an appropriate range, preferably from 3 to 10V.

In addition, the sheath voltage is associated with the pressure inside the reaction chamber. The electron density can be reduced by increasing the pressure inside the reaction chamber, and thus the electron temperature can be lowered. The lowered electron temperature can directly lead to a drop of the sheath voltage. Thus, the sheath voltage can be adjusted through adjustment of the pressure inside the reaction chamber. In the invention method, the pressure inside the reaction chamber can be controlled at 3 to 500 mTorr; the electron temperature can be controlled between 0.1 and 2 eV; and the electron density can be controlled at about 10¹⁶⁻¹⁷/cm³.

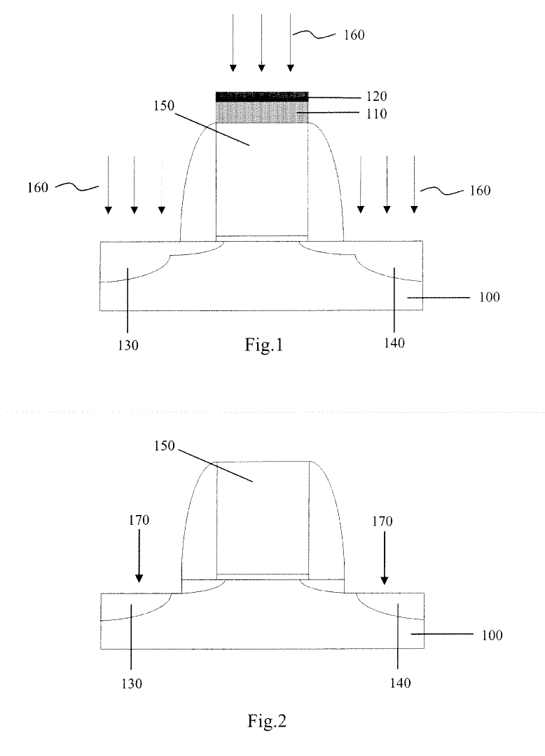

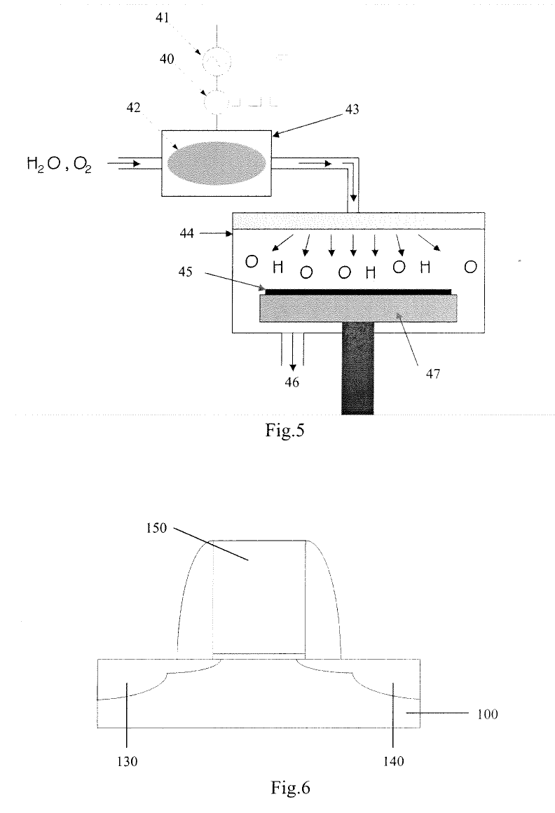

FIG. 5 shows a schematic diagram of a plasma etching apparatus according to a first embodiment of the invention, which is merely illustrative of an example without limitation of the scope of the invention. As shown, the plasma etching apparatus according to the first embodiment of the invention is also referred to as a remote plasma etching device including an RF power source 41 for generating RF power, an impedance match circuit (not shown), and a pulse control circuit 40 acting as a switch circuit for RF power output pulse. Particularly, the pulse control circuit 40 can control the RF power output through high and low pulse levels, that is, outputting RF power at a high level for excitation of the plasma, and disabling the RF power output at a low level, and further can adjust a percentage of a time range in which the RF power source outputs power relative to the whole etching time range through adjustment of a pulse width and a duty ratio. Various well-known pulse circuits can be used by the pulse control device 40, and numerous variations and modifications can be made by those skilled in the art. A remote plasma generation chamber 43 generates plasma free radicals, and feeds the free radicals into an etching reaction chamber for reaction with the wafer. The plasma etching device according the present embodiment can be used for stripping a photoresist. The photoresist can be stripped in a dry etching process using plasma, where oxygen (O₂) and water vapor (H₂O) are typically used as the etching gas. The oxygen plasma reacts with the photoresist to generate removable gases such as CO, CO₂, etc., and the vapor is typically used for removal of a chlorine element at the sidewalls and in the photoresist. After being fed into the chamber 43, O₂ and H₂O are excitated by the RF power source 41 to generate plasma 42 including hydrogen ions (H⁺) and oxygen ions (O⁺). After entering a reaction chamber 44, the hydrogen ions (H⁺) and the oxygen ions (O⁺) come into a contact with a wafer 45 on a heating plate 47. In the present embodiment, the wafer 45 is a wafer as shown in FIG. 1 including a photoresist to be stripped and an MOS device. The hydrogen ions (H⁺) and oxygen ions (O⁺) react with the photoresist on the surface of the wafer 45 to generate a gas mixture containing CO, CO₂ and H₂O, which is in turn exhausted through an exhaust port 46. In the present embodiment, the RF power source 41 outputs power in a pulse output mode. In the output period, the oxygen plasma etches the photoresist on the substrate surface, and in the dwelling period, the etching is disabled. Moreover, a percentage of a time range in which the RF power source outputs power relative to the whole etching time range can be controlled in a range of 5% to 90%. The plasma sheath voltage can be adjusted to be within an appropriate range, such as from 3 to 10V, through adjustment of the pulse width. In this way, the etching strength of the plasma for the gate oxide layer can be controlled precisely, thus achieving the purpose of controlling an etching thickness of the gate oxide layer.

FIG. 6 shows a schematic diagram of a device for which the photoresist has been stripped through the etching apparatus shown in FIG. 5, which is merely illustrative of an example without limitation of the scope of the invention. As shown, the RF power source 41 outputs in a pulse output mode, and thus the etching strength for the gate oxide layer can be controlled. The etching depth can be controlled at the depth of the gate oxide layer, resulting in no recess on the surface of the active area.

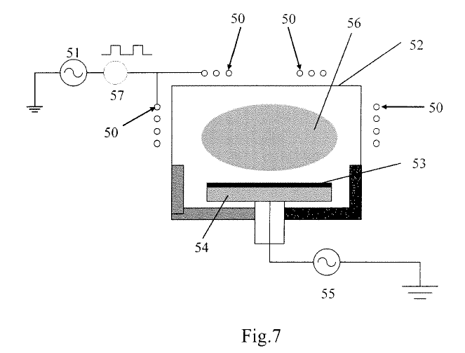

FIG. 7 shows a schematic diagram of a plasma etching apparatus according to a second embodiment of the invention, which is merely illustrative of an example without limitation of the scope of the invention. As shown, the plasma etching apparatus according to the second embodiment includes a reaction chamber 52 containing an etching gas fed thereto through a pipe (not shown), a wafer stand 54 for bearing a semiconductor wafer 53, a first RF power source 55 for providing the wafer 53 with a bias voltage, a second RF power source 51 for generating RF power, a set of coils 50 provided above and on a top of the reaction chamber 50, a second RF power source 51 for generating RF power, and a pulse control circuit 57 acting as a switch circuit for RF power output pulse. Particularly, the pulse control circuit 57 can control the RF power output through high and low pulse levels, that is, outputting RF power at a high level for excitation of the plasma, and disabling the RF power output at a low level, and further can adjust a percentage of a time range in which the RF power source outputs power relative to the whole etching time range through adjustment of a pulse width and a duty ratio. Various well-known pulse circuits can be used by the pulse control device 57, and numerous variations and modifications can be made by those skilled in the art. The second RF power source 51 is connected to the set of coils 50 via the pulse control circuit 57, and outputs RF power in a pulse output mode to the set of coils 50. The etching gas is ionized to generate plasma 56, which in turn etches a material layer of the wafer 53. The time range in which the second RF power source 51 outputs power ranging from 100 to 2200 W via the pulse control circuit 57 is 5% to 90% relative to the whole etching time range. The pressure inside the reaction chamber 52 is from 3 to 500 mTorr, and the temperature of the wafer 53 is from 20 to 180° C. The material layer can include a photoresist layer, a metal layer or a medium layer, where the metal layer can be one of copper, titanium, tungsten, tantalum, nickel and cobalt, and the medium layer can be at least one of silicon oxide, silicon nitride, silicon oxynitride, polysilicon, hafnium oxide, hafnium silicon oxide, hafnium silicon oxynitride or a combination thereof. The etching gas includes at least one of O₂, N₂, Ar, He, Ne, Cl₂, O₂—He, HBr and a fluorine-containing gas including at least one of CF₄, CH₂F₂, CHF₃ and SF₆.

The plasma etching method and apparatus according to the embodiments of the invention output power in a pulse mode, that is, the RF power source for generating plasma outputs RF power in a pulse mode, and the plasma etches a film layer to be etched in an intermittent not continuous mode. Thus the etching effect of the plasma can be controlled and buffered. With such a pulse plasma etching mode, a proportion of the time width in which the plasma source outputs power relative to the whole pulse period can be adjusted as needed, and the electron temperature and the sheath voltage of the plasma can be adjusted to be within an appropriate range. During an etching process for a semiconductor device of 65 nm and below, the inventive plasma etching method and apparatus can be suitable for etching respective layers including a photoresist layer, a metal layer or a medium layer, and can precisely control an etching depth and improve an precision of a point where the etching can be disabled. The etching depth can be controlled precisely during a process such as the stripping of the photoresist, the etching of the gate oxide layer, etc., thus resulting in elimination of any recess occurring in the active area and the LDD region.

The present invention has been described and illustrated with reference to the embodiments thereof and the drawings. It shall be recognized by those skilled in the art that those embodiments and drawings are merely illustrative and not restrictive, that the present invention shall not be limited thereto, and that various modifications and variations can be made thereto in light of the descriptions and the drawings without departing from the spirit and scope of the present invention as defined in the accompanying claims.

What is claimed is:

1. A plasma etching method comprising:
preparing in a reaction chamber a semiconductor substrate on which a material layer to be etched is provided; and
injecting an etching gas into the reaction chamber, the etching gas being ionized through an RF (Radio Frequency) power source to generate plasma, wherein:
the RF power source outputs RF power in a pulse output mode.

2. The method according to claim 1, wherein the RF power source outputs RF power ranging from 100 to 2200 W.

3. The method according to claim 1, wherein a time range for the RF power source to output RF power is of 5% to 90% relative to a whole etching time range.

4. The method according to claim 3, wherein a pressure in the reaction chamber ranges from 3 to 500 mTorr.

5. The method according to claim 1, wherein a temperature of the semiconductor substrate ranges from 20 to 180° C.

6. The method according to claim 1, wherein the material layer is a photoresist layer, a metal layer or a medium layer.

7. The method according to claim 6, wherein the metal layer is one of copper, titanium, tungsten, tantalum, nickel and cobalt.

8. The method according to claim 6, wherein the medium layer is one of silicon oxide, silicon nitride, silicon oxynitride, polysilicon, hafnium oxide, hafnium silicon oxide and hafnium silicon oxynitride.

9. The method according to claim 1, wherein the etching gas is one of O₂, N₂, Ar, He, Ne, Cl₂, O₂—He, HBr and a fluorine-containing gas.

10. The method according to claim 9, wherein the fluorine-containing gas is one of CF₄, CH₂F₂, CHF₃ and SF₆.

11. A plasma etching apparatus comprising:
a reaction chamber adapted to contain an etching gas;
an RF (Radio Frequency) power source adapted to output RF power for excitation of the etching gas to generate plasma; and
a pulse control circuit adapted to control the RF power source to output RF power in a pulse output mode.

12. The apparatus according to claim 11, wherein the RF power source outputs RF power ranging from 100 to 2200 W.

13. The apparatus according to claim 11, wherein a time range for the RF power source to output RF power is of 5% to 90% relative to a whole etching time range.

14. The apparatus according to claim 11, wherein a pressure in the reaction chamber ranges from 3 to 500 mTorr.

15. The device according to claim 11, wherein a wafer temperature ranges from 20 to 180° C.

16. A plasma etching apparatus comprising:
an RF power source adapted to output RF (Radio Frequency) power;
a pulse control circuit adapted to control the RF power source to output RF power; and
a first reaction chamber and a second reaction chamber, wherein:
the first reaction chamber contains an etching gas, the RF power source outputs RF power in a pulse output mode through the pulse control circuit, and an etching gas is ionized in the first reaction chamber to generate plasma entering the second reaction chamber to etch a material layer on a wafer surface.

17. The apparatus according to claim 16, wherein the RF power source outputs RF power ranging from 100 to 2200 W.

18. The apparatus according to claim 16, wherein a time range for the RF power source to output RF power is from 5% to 90% relative to a whole etching time range.

19. The apparatus according to claim 16, wherein a pressure in the first reaction chamber ranges from 3 to 500 mTorr.

20. The apparatus according to claim 16, wherein a temperature of the wafer ranges from 20 to 180° C.

21. The apparatus according to claim 16, wherein the etching gas comprises oxygen and water vapor.

22. The method according to claim 2, wherein a time range for the RF power source to output RF power is of 5% to 90% relative to a whole etching time range.

23. The method according to claim 22, wherein a pressure in the reaction chamber ranges from 3 to 500 mTorr.

24. The apparatus according to claim 12, wherein a time range for the RF power source to output RF power is of 5% to 90% relative to a whole etching time range.

25. The apparatus according to claim 17, wherein a time range for the RF power source to output RF power is from 5% to 90% relative to a whole etching time range.
